(19) United States
(12) Patent Application Publication
(10) Pub. No.: US 2014/0027774 A1
(43) Pub. Date: Jan. 30, 2014

(54) Laser Processed Photovoltaic Devices and Associated Methods

(71) Applicants: Xia Li, Beverly, MA (US); Christopher Vineis, Watertown, MA (US); Martin U. Pralle, Wayland, MA (US)

(72) Inventors: Xia Li, Beverly, MA (US); Christopher Vineis, Watertown, MA (US); Martin U. Pralle, Wayland, MA (US)

(73) Assignee: SiOnyx, Inc., Beverly, MA (US)

(21) Appl. No.: 13/472,075

(22) Filed: May 15, 2012

Related U.S. Application Data
(60) Provisional application No. 61/508,377, filed on Jul. 15, 2011.

(51) Int. Cl. H01L 31/105

(52) U.S. Cl. CPC H01L 31/1055
USPC 257/53

(57) ABSTRACT

Photovoltaic heterojunction devices, combination hetero- homo-junction devices, and associated methods are provided. In one aspect, for example, a photovoltaic device can include a doped semiconductor substrate having a first textured region and a second textured region opposite the first textured region, a first intrinsic semiconductor layer coupled to the first textured region opposite the semiconductor substrate and a second intrinsic semiconductor layer coupled to the second textured region opposite the semiconductor substrate. A first semiconductor layer can be coupled to the first intrinsic semiconductor layer opposite the first textured region, where the first semiconductor layer is doped to an opposite polarity of the doped semiconductor substrate. A second semiconductor layer can be coupled to the second intrinsic semiconductor layer opposite the second textured region, where the second semiconductor layer is doped to a same polarity as the semiconductor substrate but having a higher dopant concentration as the semiconductor substrate.

### PRIORITY DATA

This application claims the benefit of U.S. Provisional Patent Application Ser. No. 61/508,377, filed on Jul. 15, 2011, which is incorporated herein by reference.

### FEDERALLY SPONSORED RESEARCH

The invention was made with Government support under contract HR0011-10-C0080 awarded by Defense Advanced Research Projects Agency (DARPA). The Government has certain rights in the invention.

### BACKGROUND

Various semiconductor devices can be used to absorb and detect photons. Such photo-detecting semiconductor devices are often affected by and provide some response to interaction with electromagnetic radiation. Various ranges of electromagnetic radiation can be detected by various photo-detecting semiconductor devices, including visible range wavelengths (approximately 400 nm to 700 nm) and non-visible wavelengths (longer than about 700nm or shorter than 400 nm). The infrared spectrum is often thought of as including a near infrared portion of spectrum including wavelengths of approximately 700 to 1300 nm, a short wave infrared portion of the spectrum including wavelengths of approximately 1300 nm to 3 micrometers, and a mid to long wave infrared (or thermal infrared) portion of the spectrum including wavelengths greater than about 3 micrometers up to about 30 micrometers. These are generally and collectively referred to herein as “infrared” portions of the electromagnetic spectrum unless otherwise noted.

A heterojunction cell is a low doped single crystal silicon wafer that is coated on either side with a highly doped amorphous silicon layer, n-type on one side of the wafer and p-type on the other. The fundamental advantage of this structure is that it provides is a solar cell with a high open circuit voltage, >0.65V. This is a function of two main contributing elements. The open circuit voltage is defined by the relationship shown in Equation I:

$${V}_{oc} = \frac{kT}{q} ln ( \frac{{j}_{sc}}{{j}_{o}} + 1 ) \qquad I$$

where j_{sc}, and jₒ are the short circuit current and the dark current respectively. The doped amorphous silicon that is deposited on the crystalline silicon passivates the surface states of the substrate material and thus reduces the dark current and increases the open circuit voltage as indicated by Equation I. As the dark current is reduced the open circuit voltage logarithmically increases.

Doping amorphous silicon during deposition enables very high doping concentrations in the semiconductor material (˜10¹⁹-10²⁰/cm³). These high concentrations do not diffuse into the silicon material and hence a very sharp doped/undoped transition forms between the silicon wafer and the amorphous layer. In fact, this interface is nearly atomically sharp. These sharp transitions set up a strong field across the photovoltaic cell that promotes drift of carriers out of the device and into the circuit. This increases the carrier velocity and decreases recombination resulting in higher short circuit currents. The higher photocurrent yields higher open circuit voltage as indicated in Equation I.

### SUMMARY

The present disclosure provides photovoltaic heterojunction devices, combination hetero- homo-junction devices, and associated methods. In one aspect, for example, a photovoltaic device can include a semiconductor substrate having a first textured region and a second textured region opposite the first textured region, where the semiconductor substrate is doped. The device can also include a first intrinsic semiconductor layer coupled to the first textured region opposite the semiconductor substrate and a second intrinsic semiconductor layer coupled to the second textured region opposite the semiconductor substrate. A first semiconductor layer can be coupled to the first intrinsic semiconductor layer opposite the first textured region, where the first semiconductor layer is doped to an opposite polarity of the doped semiconductor substrate, thus forming a first junction with the semiconductor substrate. A second semiconductor layer can be coupled to the second intrinsic semiconductor layer opposite the second textured region, where the second semiconductor layer is doped to a same polarity as the semiconductor substrate but having a higher dopant concentration as the semiconductor substrate, thus forming a second junction with the semiconductor substrate. The device can also include a first electrical contact coupled to the first semiconductor layer opposite the first intrinsic semiconductor layer and a second electrical contact coupled to the second semiconductor layer opposite the second intrinsic semiconductor layer.

In another aspect, a combination heterojunction and homojunction photovoltaic device is provided. Such a device can include a semiconductor substrate having a first doped region and a bandgap, with a second doped region disposed on the first doped region, where the second doped region has an opposite polarity and a substantially equal bandgap as the first doped region such that a homojunction is formed between the first doped region and the second doped region. A textured region can be formed on the second doped region. An intrinsic semiconductor layer can be coupled to the semiconductor substrate opposite the textured region, wherein the intrinsic semiconductor layer has a substantially different bandgap as the semiconductor substrate. A doped semiconductor layer can be coupled to the intrinsic semiconductor layer opposite the semiconductor substrate. The doped semiconductor layer can be doped to a same polarity as the semiconductor substrate but having a higher dopant concentration as the semiconductor substrate. As such, a heterojunction is formed between the intrinsic semiconductor layer and the semiconductor substrate.

### BRIEF DESCRIPTION OF THE DRAWINGS

FIG. 1 is a schematic view of a photovoltaic device in accordance with one aspect of the present disclosure;

FIG. 2 is a schematic view of a photovoltaic device in accordance with another aspect of the present disclosure;

FIG. 3 is a schematic view of a photovoltaic device in accordance with yet another aspect of the present disclosure;

FIG. 4 is a schematic view of a photovoltaic device in accordance with a further aspect of the present disclosure; and

FIG. 5 is a schematic view of a photovoltaic device in accordance with yet a further aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

Definitions

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

In describing and claiming the present disclosure, the following terminology will be used in accordance with the definitions set forth below.

As used herein, the terms “disordered surface” and “textured surface” can be used interchangeably, and refer to a surface having a topology with nano- to micron-sized surface texture formed by the irradiation of laser pulses. While the characteristics of such a surface can be highly variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized crystal structures (e.g. about 2 μm to about 60 μm). In another aspect, the disordered surface can have a topology having texture ranging from 0.1 nm to 1000 μm in size. In yet another aspect, the disordered surface can have a topology having texture ranging from 0.1 nm to 100 μm in size. In a further aspect, surface structures can be from about 5 nm to about 5 μm in size. In one aspect, the size of a surface structure can be measured from the base of the structure to the tip of the structure.

As used herein, the term “fluence” refers to the amount of energy from a single pulse of laser radiation that passes through a unit area. In other words, “fluence” can be described as the energy density of one laser pulse.

As used herein, the terms “surface modifying” and “surface modification” refer to the altering of a surface of a semiconductor material using laser radiation. Surface modification can include processes using primarily laser radiation or laser radiation in combination with a dopant, whereby the laser radiation facilitates the incorporation of the dopant into a surface of the semiconductor material. Accordingly, in one aspect surface modification includes doping of a semiconductor material.

As used herein, the term “target region” refers to an area of a semiconductor material that is intended to be doped or surface modified using laser radiation. The target region of a semiconductor material can vary as the surface modifying process progresses. For example, after a first target region is doped or surface modified, a second target region may be selected on the same semiconductor material.

The term “coupled” as used herein includes both direct coupling and indirect coupling through an intermediate layer or layers. Thus, for example, when referring to a doped semiconductor layer being coupled to a crystalline semiconductor layer, it can be directly coupled thereto, or through an intermediate layer.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

It is noted that when discussing the present heterojunction photovoltaic devices, systems, and associated methods, each of these discussions can be considered applicable to each of the other embodiments, whether or not they are explicitly discussed in the context of that embodiment. Thus, for example, in discussing a specific structure used in the device, such a structure can also be used in the method of manufacturing the device, and vice versa. Also, in discussing specific details with respect to one specific device, such details are also applicable to other device embodiments.

The Disclosure

The present disclosure provides various optoelectronic devices, heterojunction and combined hetero- homo-junction photovoltaic devices and associated methods. In some cases, the bulk semiconductor substrate can be thinner than in traditional thick semiconductor photovoltaic devices. Thus, the devices of the present disclosure have a thin film heterojunction architecture having improved light absorption capabilities. One of the primary loss mechanisms in traditional thin-film photovoltaic devices is the tendency of such thin-film junctions transmit rather than absorb a significant amount of light. A textured region or surface disposed within the heterojunction improves performance. Thus the increased absorption of light improves the overall efficiency of devices incorporating such heterojunctions therein. In addition to improving performance, a heterojunction device of the present disclosure can be made using significantly less raw materials as compared to prior heterojunction devices.

Traditional thin film silicon solar cells exhibit limited light absorbing characteristics. In the case of amorphous silicon, for example, the band gap is such that light beyond 750 nm is not absorbed (as compared to 1100 nm for thick crystalline silicon). The solar spectrum has more than 50% of its energy in wavelengths longer than 750 nm. Therefore, a very large portion of the solar spectrum is not converted to electricity in thin-film amorphous solar cells. The present disclosure provides a heterojunction photovoltaic device utilizing thin semiconductor layers and a textured region that significantly increases the range of wavelengths absorbed, thus allowing efficient light absorption. This textured region thus increases performance of the device, as more light is captured. It should be noted, however, that the present scope is not limited to thin layers of semiconductor materials, and that the principles disclosed herein apply to semiconductor materials of all thicknesses.

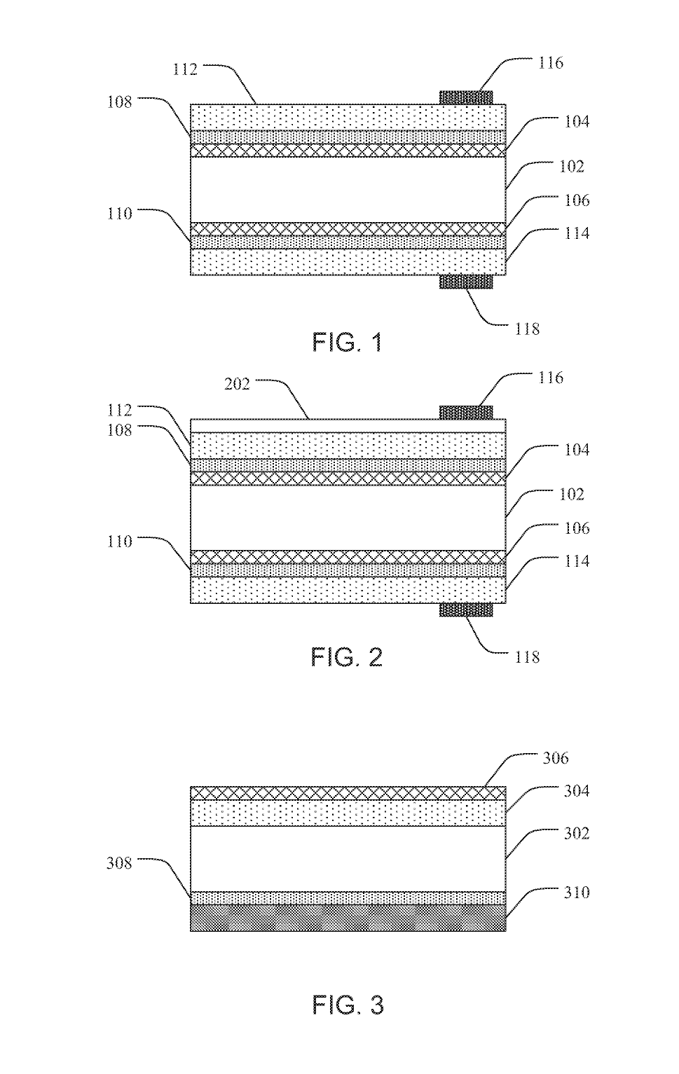

In one aspect of the present disclosure, a heterojunction photovoltaic device is shown in FIG. 1. The device can include a semiconductor substrate 102, a first textured region 104 and a second textured region 106 on an opposite side of the semiconductor substrate from the first texture region 104. The textured regions can be located across only a portion or an entire surface of the semiconductor substrate 102. In one aspect, a surface or a portion of a surface of the semiconductor substrate 102 is textured to form either of the textured regions. Furthermore, the semiconductor substrate is doped. It is contemplated that either a portion of the semiconductor substrate is doped or the entire semiconductor substrate is doped. A first intrinsic semiconductor layer 108 can be coupled to the first textured region 104 opposite the semiconductor substrate 102. A second intrinsic semiconductor layer 110 can be coupled to the second textured region 106 opposite the semiconductor substrate 102. A first semiconductor layer 112 can be coupled to the first intrinsic semiconductor layer 108 opposite the first textured region 104. The first semiconductor layer 112 can be doped to a polarity that is opposite that of the doped semiconductor substrate 102, thus forming a first junction with the semiconductor substrate 102. A second semiconductor layer 114 can be coupled to the second intrinsic semiconductor layer 110 opposite the second textured region 106. The second semiconductor layer 114 can be doped to a polarity that is the same as the polarity of the semiconductor substrate 102, but where the second semiconductor layer 114 has a higher dopant concentration (i.e. is more highly doped) as compared to the semiconductor substrate, thus forming a second junction with the semiconductor substrate 102. Furthermore, a first electrical contact 116 can be coupled to the first semiconductor layer 112 opposite the first intrinsic semiconductor layer 108 and a second electrical contact 118 can be coupled to the second semiconductor layer 114 opposite the second intrinsic semiconductor layer 110.

In one specific aspect, a semiconductor substrate 102 can have a thickness of less than 100 microns. Additionally, the first and second intrinsic semiconductor layers can have a thickness of less than about 10 nm. The first and second semiconductor layers can have a thickness of less than 30 nm.

In another specific aspect, at least one of the first intrinsic semiconductor layer or the second intrinsic semiconductor layer is an amorphous material. In another aspect, both the first intrinsic semiconductor layer and the second intrinsic semiconductor layer are amorphous materials. In one aspect, the intrinsic semiconductor layers can include amorphous silicon, amorphous germanium, or a combination or alloy thereof. In one specific aspect, the intrinsic semiconductor layer materials are amorphous silicon. In another specific aspect, at least one of the first semiconductor layer or the second semiconductor layer is an amorphous material. In another aspect, both the first semiconductor layer and the second semiconductor layer are amorphous materials.

Various doping profiles are contemplated, and any such profile that allows the formation of a heterojunction is considered to be within the present scope. For example, in one aspect the semiconductor substrate 102 can be doped to form a p-type material. As such, the first semiconductor layer 112 will be doped to form an n-type material and the second semiconductor layer 114 will be doped to form a p-type material having a higher dopant concentration compared to the semiconductor substrate 102 (e.g. p++). In another aspect, the semiconductor substrate 102 can be doped to form an n-type material. As such, the first semiconductor layer 112 will be doped to form a p-type material and the second semiconductor layer 114 will be doped to form an n-type material having a higher dopant concentration compared to the semiconductor substrate 102 (e.g. n++). Furthermore, it should be noted that the device can be utilized whereby light is initially incident on either side.

In some aspects, various additional layers can be included in the device. In one aspect, for example, a transparent oxide layer can be coupled between the first semiconductor layer and the first electrical contact. One example is shown in FIG. 2, which includes the same or similar materials as FIG. 1, with the exception of the transparent oxide layer 202. In some aspects, the first electrical contact 116 can be coupled to the transparent oxide layer 202. One non-limiting example of a transparent oxide material is indium tin oxide.

In another aspect of the present disclosure, a combination heterojunction/homojunction photovoltaic device is provided, as is shown in FIG. 3. Such a device can include a semiconductor substrate 302 having a first doped region and a second doped region 304 disposed on the first doped region. Note that in FIG. 3 the entire semiconductor substrate 302 is doped, and as such, the entire substrate is considered to be the first doped region and thus is not shown separately. In other aspects, only a portion of the semiconductor substrate is doped (not shown). The second doped region 304 can be of opposite polarity to the first doped region of the semiconductor substrate 302 such that a junction is formed between the first doped region and the second doped region. In one aspect, the material of the first doped region and the material of the second doped region have equal or substantially equal bandgaps. This, combined with the opposite doping of the regions, results in the formation of a homojunction therebetween.

Furthermore, a textured region 306 can be disposed on the second doped region 304 opposite the semiconductor substrate 302. An intrinsic semiconductor layer 308 can be coupled to the semiconductor substrate 302 opposite the textured region 306. A doped semiconductor layer 310 can be coupled to the intrinsic semiconductor layer 308 opposite the semiconductor substrate 302. The doped semiconductor layer 310 can be doped to a polarity that is the same as the polarity of the semiconductor substrate 302, but where the doped semiconductor layer 310 has a higher dopant concentration (i.e. is more highly doped) as compared to the semiconductor substrate. In one aspect, the semiconductor layer and the semiconductor substrate can have substantially different band gaps, thus forming a heterojunction between the intrinsic semiconductor layer 308 and the semiconductor substrate 302. Substantially different bandgaps can be the result of the use of different semiconductor materials in creating the junction, such as adjacent materials having different atomic structures. For example, an amorphous silicon material formed on a single crystal silicon material can result in a heterojunction, particularly if properly doped.

Various doping profiles are contemplated, and any such profile that allows the formation of a combination heterojunction/homojunction, in conjunction with the relative material bandgaps, is considered to be within the present scope. For example, in one aspect the first doped region of the semiconductor substrate 302 can be doped to form a p-type material. As such, the second doped region 304 will be doped to form an n-type material and the doped semiconductor layer 310 will be doped to form a p-type material having a higher dopant concentration compared to the semiconductor substrate 302 (e.g. p++). In another aspect, the semiconductor substrate 302 can be doped to form an n-type material. As such, the second doped region 304 will be doped to form a p-type material and the doped semiconductor layer 310 will be doped to form an n-type material having a higher dopant concentration compared to the semiconductor substrate 302 (e.g. n++). Furthermore, it should be noted that the device can be utilized whereby light is initially incident on either side.

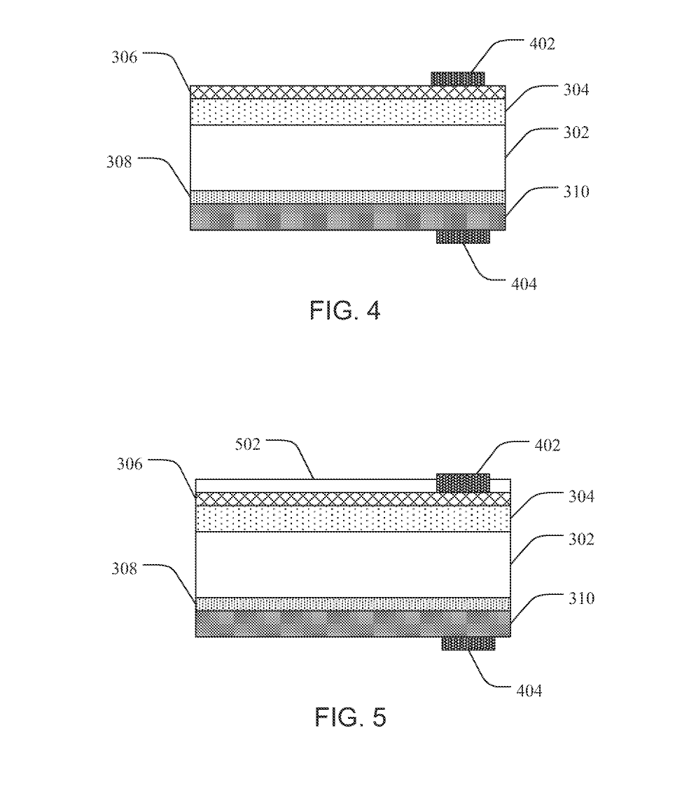

In some aspects, various additional layers can be included in the device. In one aspect, for example, electrical contacts 402, 404 can be coupled to the textured region and the doped semiconductor layer as is shown in FIG. 4. Note that callout numbers from FIG. 3 used in FIGS. 4 and 5 represent materials as described in FIG. 3. In another aspect as is shown in FIG. 5, an insulating layer 502 can be disposed on the textured region 306. Numerous insulating layer materials are contemplated, and any material that can insulate and provide functionality to the device is considered to be within the present scope. Non-limiting examples of such insulating materials include silicon nitride, silicon oxide, silicon dioxide, aluminum oxide, or a combination thereof.

In some cases, the devices according to aspects of the present disclosure can also include carrier substrates to facilitate, among other things, manipulation, manufacture, and/or use of the device. For example, a carrier substrate can be coupled to any of the semiconductor layers, the semiconductor substrate, the intrinsic layers, or the like. Such a carrier substrate can be made from any number of materials. Non-limiting examples include glass, polymer materials, ceramic materials, metal foils, and the like, including combinations thereof. Additionally, in some aspects the carrier substrate can be flexible substrate. Such a flexible substrate can be useful in making and subsequently mounting photovoltaic devices on a variety of surfaces. This may be particularly useful for non-planar surfaces. Thus, the carrier substrate can have varying levels of flexibility, from rigid to flexible. For example, in one aspect a carrier substrate can be sufficiently rigid to allow little if any planar deformation of the photovoltaic device. In another aspect, a carrier substrate can be a flexible substrate. Such a substrate can be as flexible as the photovoltaic devices allows without damage. In one aspect, a flexible substrate can be a substrate having a measureable bend radius of curvature of less than or equal to 5 cm.

A variety of semiconductor materials are contemplated for use with the devices according to aspects of the present disclosure. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. In another aspect, the semiconductor material can include at least one of silicon, carbon, germanium, aluminum nitride, gallium nitride, indium gallium arsenide, aluminum gallium arsenide, and combinations thereof.

Exemplary group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlₓGa₁₋ₓAs), indium gallium arsenide (InGaAs, InₓGa₁₋ₓAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

In some cases, the semiconductor layer materials according to aspects of the present disclosure are generally silicon materials, although any material capable of forming a heterojunction with the semiconductor substrate is considered to be within the present scope. In one aspect, germanium and silicon/germanium combinations and alloys thereof are also contemplated. As has been described, the semiconductor layers can be amorphous or crystalline. Thus, in the case of silicon, amorphous silicon materials and crystalline silicon materials can be utilized. The doping of such materials is discussed in more detail below.

The semiconductor material layers (including the semiconductor substrate) can be of any thickness that allows heterojunction and/or homojunction functionality, and thus any such thickness of semiconductor material is considered to be within the present scope. However, the textured region of the semiconductor increases the efficiency of the device such that the various semiconductor layers can be significantly thinner than has previously been possible. Decreasing the thickness of the semiconductor materials reduces the amount of the often costly semiconductor material required to make such a device. In one aspect, for example, a semiconductor layer can have a thickness of from about 0.1 μm to about 50 μm. In another aspect, a semiconductor layer can have a thickness of from about 0.01 μm to about 100 μm. In yet another aspect, a semiconductor layer can have a thickness of less than or equal to about 100 μm. In a further aspect, a semiconductor layer can have a thickness of from about 0.01 μm to about 10 μm. In yet another aspect, the crystalline semiconductor layer has a thickness of less than or equal to about 10 μm. In a further aspect, a semiconductor layer can have a thickness of from about 0.01 μm to about 1 μm. Such thin semiconductor materials can allow the manufacture of photovoltaic devices that are less than or equal to 1 μm thick.

In some aspects, semiconductor layer materials can be crystalline. Various types of crystalline semiconductor materials are contemplated, and any such material that can be incorporated into a heterojunction or homojunction device is considered to be within the present scope. In one aspect, for example, the crystalline semiconductor is monocrystalline. In another aspect, the crystalline semiconductor is multicrystalline, nanocrystalline, microcrystalline, or a combination thereof. The crystalline semiconductor materials of the present disclosure can be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth processes, and the like. Various deposition processes are contemplated, and any known deposition method is considered to be within the present scope.

The semiconductor layers according to aspects of the present disclosure, including the intrinsic layers, can be produced by any method capable of depositing such materials so as to function as a heterojunction device. In one aspect, a doped semiconductor layer can be deposited using chemical vapor deposition (CVD). CVD deposition allows the formation of semiconductor materials that are very thin, in some cases to less than a few μm thick. In one aspect, the doped semiconductor layer can be epitaxially deposited on the crystalline semiconductor layer. The formation of junctions with such thinly deposited materials allows for the manufacture of thin flexible devices, as well as a significant reduction in manufacturing materials. Thus the thicknesses of the semiconductor layers can vary depending on the intended use of the resulting devices, and the present scope should not be limited by the thicknesses such materials. In one aspect, however, a doped semiconductor layer can have a thickness of from about 0.01 μm to about 10 μm. In another aspect, a doped semiconductor layer can have a thickness of less than about 5 μm. In yet another aspect, a doped semiconductor layer can have a thickness of less than about 2 μm. In a further aspect, a doped semiconductor layer can have a thickness of less than about 1 μm.

Additionally, a passivation region or layer (i.e. an insulating layer) can be included in the various devices of the present disclosure to, among other things, reduce surface recombination in the device and provide anti-reflective properties. The passivation layer can be disposed on the semiconductor layer or layers, the semiconductor substrate, the intrinsic layers, and/or the textured region. It should be noted that any region, layer, or material of the device that can be passivated is considered to be within the present scope. The layer can be any material capable of providing passivating properties to the device, and any such material is considered to be within the present scope. Nonlimiting examples of passivation layers can include oxides or nitrides. Specific examples include silicon nitride, silicon oxide, silicon dioxide, aluminum oxide, or a combination thereof, as well as other materials known to those skilled in the art.

A variety of techniques can be utilized to form a textured region in the present devices. Such techniques can include any texturing technique that can generate a region that increases the efficiency of the photovoltaic device. In one aspect, for example, the textured region can be formed by chemical etching. In another aspect, the textured region can be formed by laser processing.

A variety of techniques of forming a textured region via laser processing are contemplated, and any technique capable of forming such a region should be considered to be within the present scope. In one aspect, for example, a target region of a semiconductor material can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a semiconductor material is irradiated with laser radiation to form a textured or surface modified region. Such laser processing can occur with or without a dopant material. In those aspects where a dopant is used, the laser can be directed through a dopant carrier and onto the semiconductor surface. In this way, dopant from the dopant carrier is introduced into the target region of the semiconductor material. Such a region incorporated into a semiconductor material can have various benefits in accordance with aspects of the present disclosure. For example, the region typically has a textured surface that increases the surface area of the laser processed region and increases the probability of photon absorption. In one aspect, such a region is a substantially textured surface including micron-sized and/or nano-sized surface features that have been generated by the laser texturing.

The type of laser radiation used to surface modify a semiconductor material can vary depending on the material and the intended modification. Any laser radiation known in the art can be used with the systems and methods of the present disclosure. There are a number of laser characteristics that can affect the surface modification process and/or the resulting product including, but not limited to the wavelength of the laser radiation, pulse width, pulse fluence, pulse frequency, polarization, laser propagation direction relative to the semiconductor material, etc. In one aspect, a laser can be configured to provide pulsatile lasing of a semiconductor material. Such laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths are in the range of from about 50 to 500 femtoseconds. In yet another aspect, laser pulse widths are in the range of from about 10 femtoseconds to about 900 picoseconds.

The number of laser pulses irradiating a semiconductor target region can be in a range of from about 1 to about 2000. In one aspect, the number of laser pulses irradiating a semiconductor target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

n-type and p-type materials can be formed by doping as well. In the case of n-type materials, doping creates an increase in the number of free negative charge carriers. In the case of p-type materials, doping creates an increase in the number of free positive charge carriers. In some aspects, variations of n(−−), n(−), n(+), n(++), p(−−), p(−), p(+), or p(++) type semiconductor layers may be used, whereby minus and positive signs are indicators of the relative strength of the doping of the semiconductor material. An intrinsic (i-type) semiconductor is typically a substantially undoped semiconductor.

A variety of dopant materials are contemplated, and any such material that can be used to modify a semiconductor material according to aspects of the present disclosure is considered to be within the present scope. Semiconductor materials can be in-situ doped, diffusion doped, implanted, and the like, including any other doping method known to those skilled in the art. It should be noted that the particular dopant utilized can vary depending on the semiconductor being surface modified, and the intended use of the resulting semiconductor material. A dopants can be either electron donating or hole donating. In one aspect, non-limiting examples of dopant materials can include S, F, B, P, N, As, Se, Te, Ge, Ar, Ga, In, Sb, and combinations thereof. It should be noted that the scope of dopant materials should include, not only the dopant materials themselves, but also materials in forms that deliver such dopants (i.e. dopant carriers). For example, S dopant materials includes not only S, but also any material capable being used to dope S into the target region, such as, for example, H₂S, SF₆, SO₂, and the like, including combinations thereof. Non-limiting examples of fluorine-containing compounds can include ClF₃, PF₅, F₂ SF₆, BF₃, GeF₄, WF₆, SiF₄, HF, CF₄, CHF₃, CH₂F₂, CH₃F, C₂F₆, C₂HF₅, C₃F₈, C₄F_{g}, NF₃, and the like, including combinations thereof. Non-limiting examples of boron-containing compounds can include B(CH₃)₃, BF₃, BCl₃, BN, C₂B₁₀H₁₂, borosilica, B₂H₆, and the like, including combinations thereof. Non-limiting examples of phosphorous-containing compounds can include PF₅, PH₃, and the like, including combinations thereof. Non-limiting examples of chlorine-containing compounds can include Cl₂, SiH₂Cl₂, HCl, SiCl₄, and the like, including combinations thereof. Dopants can also include arsenic-containing compounds such as AsH₃ and the like, as well as antimony-containing compounds. Additionally, dopant materials can include mixtures or combinations across dopant groups, i.e. a sulfur-containing compound mixed with a chlorine-containing compound. In one aspect, the dopant material can have a density that is greater than air. In one specific aspect, the dopant material can include Se, H₂S, SF₆, or mixtures thereof. In yet another specific aspect, the dopant can be SF₆ and can have a predetermined concentration range of 5.0×10⁻⁸ mol/cm³-5.0×10⁻⁴ mol/cm³. SF₆ gas is a good carrier for the incorporation of sulfur into the semiconductor material via a laser process without significant adverse effects on the semiconductor material. Additionally, it is noted that dopants can also be liquid solutions of n-type or p-type dopant materials dissolved in a solution such as water, alcohol, or an acid or basic solution. Dopants can also be solid materials applied as a powder or as a suspension dried onto the wafer.

Furthermore, the devices of the present disclosure can include multiple layers that vary in majority carrier polarity (i.e. donor or acceptor impurities). The donor or acceptor impurities are often determined by the type of dopant/impurities introduced into the semiconductor either through a growth process, deposition process, epitaxial process, implant process, lasing process, or other known process to those skilled in the art. Often, semiconductor materials can include an n-type layer, an intrinsic (i-type) layer, and a p-type layer. These layers together can collectively be referred to as a p-i-n semiconductor material stack that creates a junction. A semiconductor material devoid of an i-type layer is also contemplated.

Regarding the configuration of an i-type layer within a heterojunction device, the present scope includes any relative spatial location that allows semiconductive functionality. As has been described, the i-type layer materials according to aspects of the present disclosure are generally silicon materials, although any material capable of utilization in a heterojunction is considered to be within the present scope. In one aspect, germanium and silicon/germanium combinations and alloys thereof are also contemplated.

Of course, it is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A photovoltaic device, comprising:
a semiconductor substrate having a first textured region and a second textured region opposite the first texture region, wherein the semiconductor substrate is doped;
a first intrinsic semiconductor layer coupled to the first textured region opposite the semiconductor substrate;
a second intrinsic semiconductor layer coupled to the second textured region opposite the semiconductor substrate;
a first semiconductor layer coupled to the first intrinsic semiconductor layer opposite the first textured region, wherein the first semiconductor layer is doped to an opposite polarity of the doped semiconductor substrate, thus forming a first junction with the semiconductor substrate;
a second semiconductor layer coupled to the second intrinsic semiconductor layer opposite the second textured region, wherein the second semiconductor layer is doped to a same polarity as the semiconductor substrate but having a higher dopant concentration as the semiconductor substrate, thus forming a second junction with the semiconductor substrate;
a first electrical contact coupled to the first semiconductor layer opposite the first intrinsic semiconductor layer; and
a second electrical contact coupled to the second semiconductor layer opposite the second intrinsic semiconductor layer.

2. The device of claim 1, further comprising a transparent oxide layer coupled between the second semiconductor layer and the second electrical contact.

3. The device of claim 1, wherein at least one of the first intrinsic semiconductor layer or the second intrinsic semiconductor layer is amorphous.

4. The device of claim 1, wherein at least one of the first semiconductor layer or the second semiconductor layer is amorphous.

5. The device of claim 1, wherein at least one of the first textured surface or the second textured surface has surface features with a size from about 5 nm to about 5 microns.

6. The device of claim 1, wherein at least one of the first textured surface or the second textured surface is laser textured with a laser having a pulse duration of from about 10 femtoseconds to about 900 picoseconds.

7. The device of claim 1, wherein at least one of the first textured surface or the second textured surface is a chemically textured surface.

8. The device of claim 1, wherein one of the first textured surface or the second textured surface is laser textured with a laser having a pulse duration of from about 10 femtoseconds to about 900 picoseconds, and the other of the first textured surface or the second textured surface is a chemically textured surface.

9. The device of claim 1, wherein the semiconductor substrate, the first intrinsic semiconductor layer, the first semiconductor layer, the second intrinsic semiconductor layer, and the second semiconductor layer independently include a member selected from the group consisting of group IV materials, compounds and alloys comprising materials from groups II and VI, compounds and alloys comprising materials from groups III and V, and combinations thereof.

10. The device of claim 1, wherein at least one of the semiconductor substrate, the first intrinsic semiconductor layer, the first semiconductor layer, the second intrinsic semiconductor layer, or the second semiconductor layer is silicon.

11. A combination heterojunction and homojunction photovoltaic device, comprising:
a semiconductor substrate including a first doped region and a bandgap;
a second doped region disposed on the first doped region, the second doped region having an opposite polarity and a substantially equal bandgap as the first doped region such that a homojunction is formed between the first doped region and the second doped region;
a textured region disposed on the second doped region opposite the first doped region;
an intrinsic semiconductor layer coupled to the semiconductor substrate opposite the textured region, wherein the intrinsic semiconductor layer has a substantially different bandgap as the semiconductor substrate; and
a doped semiconductor layer coupled to the intrinsic semiconductor layer opposite the semiconductor substrate, wherein the doped semiconductor layer is doped to a same polarity as the semiconductor substrate but having a higher dopant concentration as the semiconductor substrate;
wherein a heterojunction is formed between the intrinsic semiconductor layer and the semiconductor substrate.

12. The device of claim 11, further comprising a first electrical contact coupled to the textured region opposite the semiconductor substrate.

13. The device of claim 11, further comprising a second electrical contact coupled to the doped semiconductor layer opposite the intrinsic semiconductor layer.

14. The device of claim 11, further comprising an insulating layer disposed on the textured region.

15. The device of claim 14, wherein the insulating layer includes a material selected from the group consisting of silicon nitride, silicon oxide, silicon dioxide, aluminum oxide, or a combination thereof.

16. The device of claim 11, wherein the textured region has surface features with a size from about 5 nm to about 5 microns.

17. The device of claim 11, wherein the textured region is laser textured with a laser having a pulse duration of from about 10 femtoseconds to about 900 picoseconds.

18. The device of claim 11, wherein the textured region is a chemically textured surface.

19. The device of claim 11, wherein the semiconductor substrate is silicon.

20. The device of claim 19, wherein the silicon includes a member selected from the group consisting of monocrystalline, substantially monocrystalline, multicrystalline, microcrystalline, polycrystalline, or a combination thereof.

21. The device of claim 11, wherein at least one of the doped semiconductor layer or the intrinsic semiconductor layer is a member selected from the group consisting of amorphous silicon, amorphous germanium, or a combinations or an alloy thereof.
